(19) United States
(12) Patent Application Publication
(10) Pub. No.: US 2011/0100458 A1
(43) Pub. Date: May 5, 2011

(54) Multi-layer thin film for encapsulation and method thereof

(75) Inventors: Jae-Wook KANG, Gyeongsangnam-do (KR); Do-Geun Kim, Gyeongsangnam-do (KR); Dong Kwon Choi, Gyeonggi-do (KR); Yong Soo Jeong, Gyeongsangnam-do (KR); Jong Kuk Kim, Gyeongsangnam-do (KR)

(73) Assignee: KOREA INSTITUTE OF MACHINERY AND MATERIALS, Daejeon (KR)

(21) Appl. No.: 12/895,958

(22) Filed: Oct. 1, 2010

(30) Foreign Application Priority Data
Nov. 5, 2009 (KR) 10-2009-016497

(51) Int. Cl. H01L 31/04; H01L 51/52; B32B 9/04; B32B 15/04; B32B 5/00; B05D 1/36; C23C 16/40; C23C 16/34; H01L 31/0203; H01L 31/0224

(52) U.S. Cl. 136/259; 257/40; 428/446; 428/336; 428/76; 427/419.2; 427/255.395; 427/579; 257/E51.018; 977/734

(57) ABSTRACT

A multi-layer thin film for encapsulation and the method thereof are provided. The multi-layer thin film for encapsulation includes a protective layer composed of aluminum oxide, a single or double barrier layer composed of silicon nitride (SiNₓ), and a mechanical protective layer composed of silicon dioxide (SiO₂). The multi-layer thin film can be economically fabricated by using the existing equipment, and has a high level of light transmission over 85% while showing a low level of oxygen and moisture penetration. Additionally, due to superior adhesive strength between the thin films, and high resistance against impacts by heat or ion during a fabricating process, reliability of fabrication is enhanced, and it can thus efficiently used in encapsulating an organic light-emitting device (OLED), a flexible organic light emitting device (FOLED) in a display field, and the cells such as a thin film battery and a solar cell.

### CROSS-REFERENCE TO RELATED APPLICATIONS

This application claims priority from Korean Patent Application No. 10-2009-106497, filed on Nov. 5, 2009, in the Korean Intellectual Property Office, the disclosure of which is incorporated herein by reference in its entirety.

### BACKGROUND OF THE INVENTION

1. Field of the Invention

Films and methods consistent with what is described herein relate to a multi-layer thin film for encapsulation and a method thereof.

2. Description of the Related Art

Generally, a multi-layer thin film for encapsulation is produced by coating organic and inorganic substances in an alternate sequence on top of a device. Function of an organic thin film of the multi-layer thin film is to absorb film stress and regulate the surface roughness so that an inorganic thin film can have a planarizing layer when the inorganic thin film that blocks oxygen and moisture is coated.

U.S. Pat. No. 6,570,325 discloses a planarizing film that is used as an organic thin film attached to upper portion of the device. This organic thin film reduces defects in the substrate to improve surface roughness and cover the particles that may be located at upper portion of the device, thereby improving the characteristics of the inorganic thin film.

As disclosed in U.S. Pat. No. 5,902,641, a liquid monomer is evaporated by a heat source to be then formed on upper portion of the device, and then subjected to a phase change of the liquid monomer into a solid phase and polymerization by UV curing, thereby manufacturing a thin film for encapsulation.

The effect from improvement in surface roughness and particle coverage achieved by reducing defects in the substrate is outstanding. However, it is impossible to obtain a planarizing layer, since the liquid monomer gathers toward the relatively larger surface. Furthermore, controlling penetration of oxygen and moisture through upper portion of the particle is very hard.

Whereupon, we developed a multi-layer thin film for encapsulation and a method thereof, the multilayer thin film comprising: a protective layer composed of aluminum oxide produced by a chemical method; a single or double barrier layer composed of silicon nitride (SiNₓ); and a mechanical protective layer composed of silicon dioxide (SiO₂). The multi-layer thin film can be economically fabricated by using the existing equipment, and has a high level of light transmission over 85% while showing a low level of oxygen and moisture penetration. Additionally, due to superior adhesive strength between the thin films, and high resistance against impacts by heat or ion during a fabricating process, reliability of fabrication is enhanced, and it can thus efficiently used in encapsulating an organic light-emitting device (OLED), a flexible organic light emitting device (FOLED) in a display field, and the cells such as a thin film battery and a solar cell.

### SUMMARY OF THE INVENTION

It is an object of the present invention to provide a multi-layer thin film for encapsulation with a great safety.

It is another object of the present invention to provide a method for producing the multi-layer thin film for encapsulation.

According to one embodiment, a multi-layer thin film for encapsulation including a protective layer, a barrier layer, and a mechanical protective layer is provided.

According to another embodiment, a method for producing the film is provided.

The multi-layer thin film can be economically fabricated by using the existing equipment, and has a high level of light transmission over 85% while showing a low level of oxygen and moisture penetration. Additionally, due to superior adhesive strength between the thin films, and high resistance against impacts by heat or ion during a fabricating process, reliability of fabrication is enhanced, and it can thus efficiently used in encapsulating an organic light-emitting device (OLED), a flexible organic light emitting device (FOLED) in a display field, and the cells such as a thin film battery and a solar cell.

### BRIEF DESCRIPTION OF THE DRAWINGS

The above and/or other aspects of what is described herein will be more apparent by describing certain exemplary embodiments with reference to the accompanying drawings, in which:

FIG. 1 illustrates an embodiment according to the present invention;

FIG. 2 illustrates an embodiment according to the present invention;

FIG. 3 illustrates an embodiment according to the present invention;

FIG. 4 illustrates an embodiment according to the present invention;

FIG. 5 illustrates a graphical representation of the result of Experiment 1 which measured life span of the organic light emitting device (OLED) according to an embodiment.

### DETAILED DESCRIPTION OF EXEMPLARY EMBODIMENTS

Certain exemplary embodiments will now be described in greater detail with reference to the accompanying drawings.

In one embodiment, a multi-layer thin film for encapsulation may include a protective layer composed of aluminum oxide, a single or double barrier layer composed of silicon nitride (SiNₓ), and a mechanical protective layer composed of silicon dioxide (SiO₂), which are deposited on one another in sequence.

According to one embodiment, the multi-layer thin film for encapsulation includes a protective layer, a barrier layer, and a mechanical protective layer, and this is able to prevent substrate damages caused by heat or ion during a fabrication process, avoid short and dark spots on the device by preventing a Joule heating phenomenon, and provide a high level of light transmission over 85%, and subsequently low level of oxygen and moisture penetration.

According to one embodiment, the thin film for encapsulation includes the protective layer composed of aluminum oxide with thickness of 1˜30 nm located bottom the barrier layer. If the thickness is under 1 nm, the substrate or device can be damaged while the encapsulated film is deposited. If the thickness is over 30 nm, time to deposit the aluminum oxide protective layer is extended.

Damages to a substrate, a metal electrode, or a transparent conductive oxide (transparent electrode) caused by heat or ion when forming a protective layer by using the conventional plasma technology can be prevented through deposition of an aluminum oxide atomic layer on the substrate, the metal electrode, or the transparent conductive oxide (transparent electrode) using a chemical method. The protective layer may be preferably aluminum oxide (Al₂O₃).

A single or double barrier layer blocks oxygen and moisture from permeating into the device. Without the barrier layer, the mechanical protective layer alone may not prevent the device from breakage and deteriorated performance. Thickness of the barrier layer may be preferably between approximately 100˜500 nm.

The mechanical protective layer is formed on the outer-most portion of the device to protect the device from mechanical and physical impacts from outside as well as permeation of oxygen and moisture. The thickness of the barrier layer may be preferably between approximately 1μ20 μm. If the thickness is under 1 μm, the device can be damaged by the external factors. If the thickness is over 20 μm, the mechanical protective layer may have cracks.

In one embodiment, a thin film for encapsulation may be formed on the substrate and upper portion of the device located on upper portion of the substrate to seal the device. The thin film for encapsulation may also be sealed on the side or lower portion of the substrate.

In one embodiment, a method for fabricating a multi-layer film for encapsulation may include the steps of: S(1) forming an aluminum oxide protective layer; S(2) forming a single or double silicon nitride (SiNₓ) barrier layer; and S(3) forming a mechanical protective layer.

According to one embodiment, at (S1), an aluminum oxide protective layer is formed. This process is performed to protect the substrate or device from possible damages when the film for encapsulation is formed, and from permeation of oxygen and moisture. The aluminum oxide protective layer may be coated through an atomic layer deposition (ALD) by using ozone (O₃) as an oxidant source. More specifically, the aluminum oxide layer may be fabricated by heating the substrate or the OLED device approximately at 30˜80° C., supplying a tri-methyl aluminum (TMA) source to a reaction chamber with Ar carrier gas, and supplying ozone thereto. Herein, the thickness of the thin film may be increased by regularly supplying tri-methyl aluminum and ozone. After supplying the individual source, by regularly supplying Ar gas, non-reaction source is eliminated. Ozone is supplied through an external ozone generator. The thickness of the aluminum oxide layer may be preferably between approximately 0.05˜0.1 nm/cycle, and 1˜30 nm.

According to one embodiment, at S(2), a barrier layer composed of silicon nitride (SiNₓ) is performed.

Accordingly, the aluminum oxide layer may be formed at S(1) and the silicon nitride barrier layer may be formed by a plasma enhanced chemical vapor deposition (PECVD). Specifically, a silicon nitride layer with thickness of approximately 100˜500 nm may be formed in a condition where silane gas (SiH₄) and nitrogen gas (N₂), or silane gas, nitrogen gas, and ammonia gas are injected.

According to the method for producing a multi-layer film for encapsulation, at S(3), a mechanical protective layer is formed.

At S(3), a mechanical protective layer with thickness of approximately 1˜20 μm may be formed by spraying an oxide silicon solution in a sol-gel phase while exerting a pressure with air or nitrogen.

In one embodiment, an organic light emitting device may include: (a) a substrate/a transparent conductive oxide/an organic layer/a metal electrode/the thin film for encapsulation; (b) a substrate/a metal electrode/an organic layer/a transparent conductive oxide/the thin film for encapsulation; (c) a substrate/the thin film for encapsulation/a transparent conductive oxide/an organic layer/a metal electrode; or (d) a substrate/the thin film for encapsulation/a metal electrode/an organic layer/a transparent conductive oxide, which are laminated on one another in sequence.

The substrate may be a flexible polymer substrate selected from the group consisting of polyethyleneterephthalate (PET), polyethylenenaphthalate (PEN), polyethylen (PE), polyether sulfone (PES), polycarbonate (PC), polyarylate (PAR), and polyimide (PI), a metal substrate selected from a group consisting of steel use stainless (SUS), aluminum, steel, and copper, or a glass substrate. The transparent conductive oxide (TCO) may be one selected from the group consisting of indium tin oxide (ITO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO), and aluminum zinc oxide-silver-aluminum zinc oxide (AZO—Ag—Azo), or a mixture thereof.

The metal electrode may be one selected from a group consisting of a lithium fluoride-aluminum (LiF/Al) layer, a calcium-aluminum (Ca/Al) layer, a calcium-silver (Ca/Ag) layer, aluminum (Al), silver (Ag), gold (Au), and copper (Cu), or a mixture thereof.

The organic layer may preferably include a hole transport layer (HTL), a light emitting layer, an electron transport layer, and an exciton inhibition layer. The organic layer may be one selected from a group consisting of N,N′-Di (naphthalene-1-yl)-N, N′-diphenyl-benzidine (NPB); copper phthalocyanine (CuPc); 4, 4′, 4″-tris (2-naphthylphenylamino) triphenylamine(2-TNATA); 1, 1-BIS-(4-bis(4-tolyl)-aminophenyl)cyclohexene(TAPC); tris-8-hydroxyquinoline aluminum (Alq3), spiro-TAD, TAZ, Ir (ppz) 3, bathophenanthroline (BPhen), and bathocuproine (BCP), or a mixture thereof.

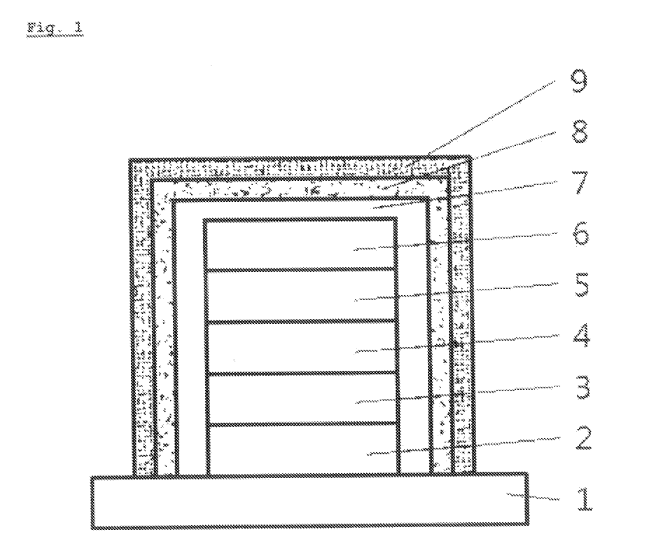

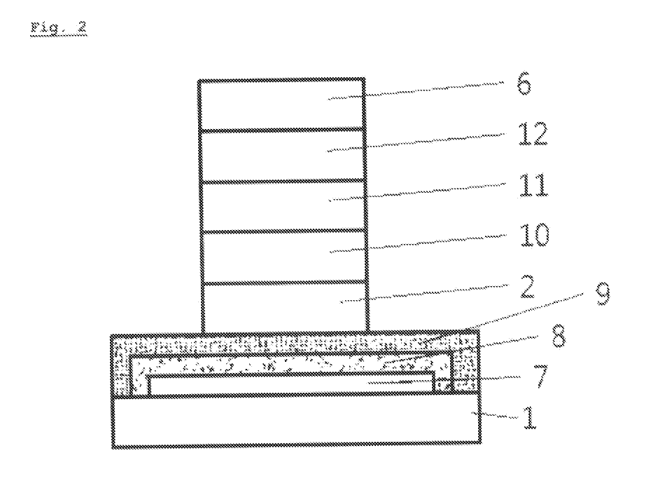

FIGS. 1 and 2 illustrate embodiment of the present invention concept.

In another embodiment, an organic solar cell may include: (a) a substrate/a transparent conductive oxide/an organic layer/a metal electrode/the thin film for encapsulation; (b) a substrate/a metal electrode/an organic layer/a transparent conductive oxide/the thin film for encapsulation; (c) a substrate/the thin film for encapsulation/a transparent conductive oxide/an organic layer/a metal electrode; or (d) a substrate/the thin film for encapsulation/a metal electrode/an organic layer/a transparent conductive oxide, which are deposited on one another in sequence.

The substrate may be a flexible polymer substrate selected from the group consisting of polyethyleneterephthalate (PET), polyethylenenaphthalate (PEN), polyethnlen (PE), polyether sulfone (PES), polycarbonate (PC), polyarylate (PAR), and polyimide (PI), a metal substrate selected from a group consisting of steel use stainless (SUS), aluminum, steel, and copper, or a glass substrate. The transparent conductive oxide (TCO) may be one selected from the group consisting of indium tin oxide (ITO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO), and aluminum zinc oxide-silver0 aluminum zinc oxide (AZO—Ag—Azo), or a mixture thereof. The metal electrode may be one selected from a layer composed of lithium fluoride and aluminum (LiF/Al), a layer composed of calcium and aluminum (Ca/Al), a layer composed of calcium and silver (Ca/Ag), and aluminum (Al), silver (Ag), gold (Au), and copper (Cu), or mixture of these elements.

The metal electrode may be one selected from the group consisting of a lithium fluoride-aluminum (LiF/Al) layer, a calcium-aluminum (Ca/Al) layer, a calcium-silver (Ca/Ag) layer, aluminum (Al), silver (Ag), gold (Au), and copper (Cu), or a mixture thereof.

The organic layer may preferably include a p-type conductive layer, a light absorbing layer, and a n-type conductive layer. The organic layer may be one selected from the group consisting of NiO, PEDOT:PSS, a polythiophene derivative, a polypyrrole derivative, a poly vinyl carbarzole derivative, a polyaniline derivative, a polyacetylene derivative, a polypenylen vinylen derivative, a fullerene derivative, ZnO, TiO₂, and WO₃, or a mixture thereof.

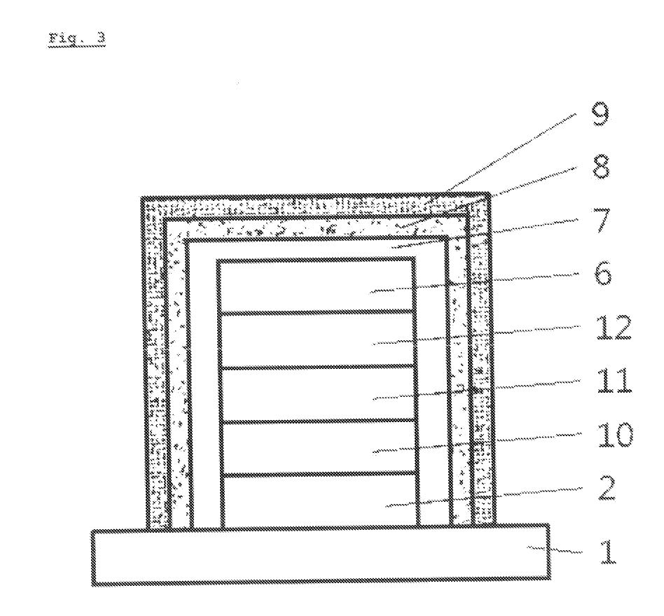

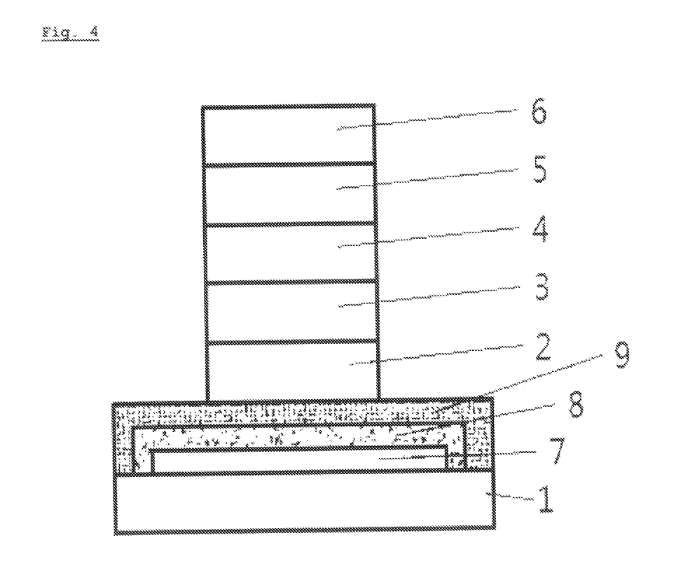

FIGS. 3 and 4 illustrate embodiment of the present invention concept.

The present inventive concept will be explained in detail below, with reference to embodiments. However, it is apparent that the present inventive concept is not confined to the specific embodiments explained below.

### Embodiment 1

Fabricating A Multi-Layer Thin Film For Encapsulation Including An Aluminum Oxide Protective Layer

Step 1: Forming An Aluminum Oxide Protective Layer.

An aluminum oxide layer was formed by heating substrate or the OLED device at 30˜80° C., supplying a tri-methyl aluminum (TMA) source to a reaction chamber through Ar carrier gas, and supplying ozone thereto. Rate of forming the aluminum oxide layer was 0.05˜0.1 nm/cycle, and the aluminum oxide protective layer with thickness of 10 nm was formed at 100˜200 cycle.

Step 2: Forming a silicon nitride barrier layer.

The silicon nitride barrier layer with thickness of 500 nm was formed by injecting silane gas (SiH₄) and nitrogen gas (N₂) respectively at 100 sccm, carried out PECVD, at 150 W (10 W/cm²) of RF power and under 100 mTorr of processing pressure for 25 minutes.

Step 3: Forming a silicon dioxide mechanical protective layer.

Using a spray method, oxide silicon solution in a sol-gel phase was discharged at 1˜100 ml/min and while exerting pressure of 10˜100 psi of air or nitrogen (N₂). Thereafter, the discharged oxide silicon solution was dried at 80° C., leaving a silicon dioxide mechanical protective layer. The hardness of the formed layer was about 9 H by pencil hardness.

The film for encapsulation fabricated by the above-mentioned process exhibited a high level of light transmission over 90%.

### Embodiment 2

Fabricating A Multi-Layer Thin Film For Encapsulation Including An Aluminum Oxide Protective Layer

The film was fabricated in the same manner as embodiment 1, except that the aluminum oxide protective layer of 20 nm was formed at step 1.

### Embodiment 3

Fabricating A Multi-Layer Thin Film For Encapsulation Including An Aluminum Oxide Protective Layer

The film was fabricated in the same manner as embodiment 1, except that the aluminum oxide protective layer of 30 nm was formed at step 1.

### Comparative Example 1

An Organic Light Emitting Device Sealed By A Glass Can

An OLED was fabricated by depositing 2-TNATA of 60 nm on ITO, depositing NPB of 20 nm and Alq3 of 60 nm with a thermal evaporator, and depositing LiF of 1 nm and 100 nm Al with a cathode. The OLED was sealed by a glass can.

### Experiment 1

Measuring Life-Time of the OLED Wherein the Thin Film For Encapsulation Is Formed.

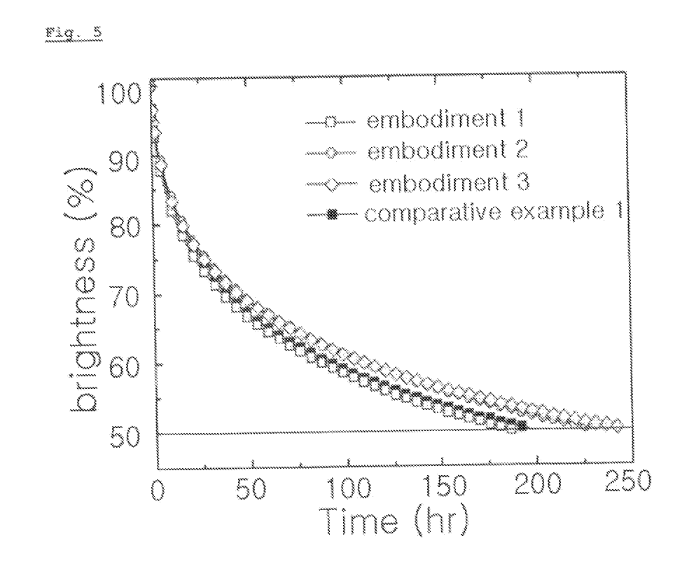

Life-times were measured by measuring the rate of reduction of brightness of the OLED by time in which the thin film for encapsulation is fabricated through embodiments 1˜3 and the comparative example 1, and the result is shown in FIG. 5.

As shown in FIG. 5, it took 205 hours of half life-time, time to reach 50% of the initial brightness, for the OLED sealed with a glass cap (comparative example 1). In embodiment 1, it took 190 hours, in embodiment 2, it took 230 hours, and in embodiment 3, it took 240 hours.

Although the present invention has been described with reference to preferred embodiments, workers skilled in the art will recognize that changes may be made in form and detail without departing from the spirit and scope of the invention.

What is claimed is:

1. A multi-layer thin film for encapsulation comprising:
a protective layer composed of aluminum oxide;
a single or double barrier layer composed of silicon nitride (SiNₓ); and
a mechanical protective layer composed of silicon dioxide (SiO₂), which are deposited on one another in sequence.

2. The multi-layer thin film for encapsulation of claim 1, wherein the protective layer composed of aluminum oxide has thickness of approximately 1˜30 nm.

3. The multi-layer thin film for encapsulation of claim 1, wherein the barrier layer composed of silicon nitride has thickness of approximately 100˜500 nm.

4. The multi-layer thin film for encapsulation of claim 1, wherein the mechanical protective layer composed of silicon dioxide has thickness of approximately 1˜20 μm.

5. The multi-layer thin film for encapsulation of claim 1, wherein the film is coated at upper portion of a device located on upper portion of a substrate to seal the device.

6. The multi-layer thin film for encapsulation of claim 1, wherein the film is coated on a substrate and at the side and bottom part of the substrate.

7. A fabrication method of a multi-layer film for encapsulation, comprising:
forming an aluminum oxide protective layer;
forming a single or double silicon nitride (SiNₓ) barrier layer; and
forming a mechanical protective layer.

8. The method of claim 7, wherein the forming the aluminum oxide protective layer comprises forming the aluminum oxide protective layer through atomic layer deposition (ALD) using ozone (O₃) as an oxidant source.

9. The method of claim 7, wherein the forming the silicon nitride barrier layer comprises forming the silicon nitride barrier layer through plasma enhanced chemical vapor deposition (PECVD).

10. An organic light emitting device (OLED) comprising:
(a) a substrate/a transparent conductive oxide/an organic layer/a metal electrode/the thin film for encapsulation deposited in sequence;
(b) a substrate/a metal electrode/an organic layer/a transparent conductive oxide/the thin film for encapsulation deposited in sequence;
(c) a substrate/the thin film for encapsulation/a transparent conductive oxide/an organic layer/a metal electrode deposited in sequence; or
(d) a substrate/the thin film for encapsulation/a metal electrode/an organic layer/a transparent conductive oxide deposited in sequence.

11. The OLED of claim 10, wherein the substrate may be a flexible polymer substrate selected from the group consisting of polyethyleneterephthalate (PET), polyethylenenaphthalate (PEN), polyethylen (PE), polyether sulfone (PES), polycarbonate (PC), polyarylate (PAR), and polyimide (PI), a metal substrate selected from a group consisting of steel use stainless (SUS), aluminum, steel, and copper, or a glass substrate.

12. The OLED of claim 10, wherein the transparent conductive oxide (TCO) may be one selected from the group consisting of indium tin oxide (ITO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO), and aluminum zinc oxide-silver-aluminum zinc oxide (AZO—Ag—Azo).

14. The OLED of claim 10, wherein the organic layer maybe one selected from a group consisting of N, N′-Di (naphthalene-1-yl)-N, N′-diphenyl-benzidine (NPB), copper phthalocyanine (CuPc), 4, 4′, 4″-tris (2-naphthylphenylamino) triphenylamine(2-TNATA), 1, 1-BIS-(4-bis(4-tolyl)-aminophenyl)cyclohexene(TAPC), tris-8-hydroxyquinoline aluminum (Alq3), spiro-TAD, TAZ, Ir (ppz) 3, bathophenanthroline (BPhen), and bathocuproine (BCP), or a mixture thereof.

15. An organic solar cell comprising:
(a) a substrate/a transparent conductive oxide/an organic layer/a metal electrode/the thin film for encapsulation deposited on one another in sequence;
(b) a substrate/a metal electrode/an organic layer/a transparent conductive oxide/the thin film for encapsulation deposited on one another in sequence;
(c) a substrate/the thin film for encapsulation/a transparent conductive oxide/an organic layer/a metal electrode deposited on one another in sequence; or
(d) a substrate/the thin film for encapsulation/a metal electrode/an organic layer/a transparent conductive oxide deposited on one another in sequence.

16. The organic solar cell of claim 15, wherein the transparent conductive oxide (TCO) may be selected from a group consisting of indium tin oxide (ITO), indium zinc oxide (IZO), indium zinc tin oxide (IZTO), aluminum zinc oxide (AZO), indium tin oxide-silver-indium tin oxide (ITO—Ag—ITO), indium zinc oxide-silver-indium zinc oxide (IZO—Ag—IZO), indium zinc tin oxide-silver-indium zinc tin oxide (IZTO—Ag—IZTO), and aluminum zinc oxide-silver-aluminum zinc oxide (AZO—Ag—Azo).

17. The organic solar cell of claim 15, wherein the metal electrode may be selected from a group consisting of a lithium fluoride-aluminum (LiF/Al) layer, a calcium-aluminum (Ca/Al) layer, a calcium-silver (Ca/Ag) layer, aluminum (Al), silver (Ag), gold (Au), and copper (Cu).

18. The organic solar cell or claim 15, wherein the organic layer may be the one selected from a group consisting of NiO, PEDOT:PSS, a polythiophene derivative, a polypyrrole derivative, a poly vinyl carbarzole derivative, a polyaniline derivative, a polyacetylene derivative, a polypenylen vinylen derivative, a fullerene derivative, ZnO, TiO₂, and WO₃, or a mixture thereof.
